(19) United States
(12) Patent Application Publication
(10) Pub. No.: US 2014/0043065 A1
(43) Pub. Date: Feb. 13, 2014

(54) DRIVER CIRCUIT, DRIVER ARCHITECTURE AND DRIVING METHOD THEREOF

(71) Applicant: NOVATEK MICROELECTRONICS CORP., Hsinchu (TW)

(72) Inventors: Ching-Ho HUNG, Hsinchu City (TW); Yueh-Hsun TSAI, Taipei City (TW)

(73) Assignee: NOVATEK MICROELECTRONICS CORP., Hsinchu (TW)

(21) Appl. No.: 13/960,240

(22) Filed: Aug. 6, 2013

(30) Foreign Application Priority Data
Aug. 10, 2012 (TW) 101129047

(51) Int. Cl. H03K 3/01

(52) U.S. Cl. CPC H03K 3/01
USPC 327/108

(57) ABSTRACT

A driver architecture includes multiple drivers connected in series. An (i)^{th} driver includes a reading circuit, a configuration circuit, a clock generator and a data input/output start pulse (DIO) generation circuit. The reading circuit reads an (i)^{th} DIO outputted from an (i−1)^{th} driver according to multiple reading pulses. The (i)^{th} DIO includes an (i−1)^{th} configuration of an (i−1)^{th} driver and an (i)^{th} trigger pulse. The (i)^{th} trigger pulse is for activating the (i)^{th} driver. The configuration circuit configures an (i)^{th} configuration of the (i)^{th} driver. The clock generator generates an (i+1)^{th} trigger pulse for activating an (i+1)^{th} driver. The DIO generation circuit outputs an (i+1)^{th} DIO to the (i+1)^{th} driver. The (i+1)^{th} DIO includes the (i)^{th} configuration and the (i+1)^{th} trigger pulse.

This application claims the benefit of Taiwan application Serial No. 101129047, filed Aug. 10, 2012, the subject matter of which is incorporated herein by reference.

### BACKGROUND OF THE INVENTION

1. Field of the Invention

The invention relates to a driver circuit, a driver architecture, and a driving method thereof.

2. Description of the Related Art

In a structure of a conventional liquid crystal display (LCD) module, source drivers or gate drivers are connected in series by utilizing only data input/output start pulses (DIO). Each of the drivers receives a DIO sent from a driver of the previous stage and becomes activated, and then transmits its DIO to a driver of the next stage. Under the above architecture, an additional driver pin is needed if data transmission or configuration is desired between the drivers, leading to increased costs.

### SUMMARY OF THE INVENTION

The disclosure is directed to a driver architecture and driving method thereof. By building a reading circuit and a data input/output start pulse (DIO) generation circuit in a driver, functions of the driver can be enhanced without changing an existing architecture.

According to an aspect, a driver architecture including multiple drivers connected in series is provided. An (i)^{th} driver includes a reading circuit, a configuration circuit, a clock generator and a data input/output start pulse (DIO) generation circuit, where i is a positive integer greater than 1. The reading circuit reads an (i)^{th} DIO outputted from an (i−1)^{th} driver according to multiple reading pulses. The (i)^{th} DIO includes an (i−1)^{th} configuration of an (i−1)^{th} driver and an (i)^{th} trigger pulse. The (i)^{th} trigger pulse is for activating the (i)^{th} driver. The configuration circuit configures an (i)^{th} configuration of the (i)^{th} driver. The clock generator generates an (i+1)^{th} trigger pulse for activating an (i+1)^{th} driver. The DIO generation circuit outputs an (i+1)^{th} DIO to the (i+1)^{th} driver. The (i+1)^{th} DIO includes the (i)^{th} configuration and the (i+1)^{th} trigger pulse.

According to another aspect, a driving method for a driver architecture is provided. The driver architecture includes multiple drivers connected in series. The driving method comprises reading by an (i)^{th} driver an (i)th data input/output start pulse (DIO) outputted from an (i−1)^{th} driver; the (i)^{th} DIO comprising configuration information and an (i)th trigger pulse, wherein i is a positive integer greater than 1, activating the (i)^{th} driver by the (i)^{th} trigger pulse, configuring a configuration of the (i)^{th} driver according to the configuration information, generating by the (i)^{th} driver an (i+1)^{th} trigger pulse for activating an (i+1)^{th} driver, and outputting by the (i)^{th} driver an (i+1)^{th} DIO to the (i+1)^{th} driver; the (i+1)^{th} DIO comprising the configuration information and the (i+1)^{th} trigger pulse.

According to further another aspect, a driver architecture is provided, comprising: a plurality of drivers connected in series. A first driver of the drivers outputs a data input/output start pulse (DIO) comprising configuration information and a trigger pulse. Each driver except the first one of the drivers reads a respective first DIO outputted from a precedent driver of the drivers, activated by a respective first trigger pulse in the respective first DIO and configured according to the configuration information in the respective first DIO, and outputs a respective second DIO to a next driver of the drivers, the respective second DIO comprising the configuration information and a respective second trigger pulse.

According to still another aspect, a driver circuit is provided, comprising: a reading circuit, for reading a data input/output start pulse (DIO), the DIO comprising configuration information for configuring a configuration of the driver circuit and a first trigger pulse for activating the driver circuit, a configuration circuit for configuring a configuration of the driver circuit according to the configuration information, a clock generator, for generating a second trigger pulse for activating another driver, and a DIO generation circuit, for outputting a DIO signal comprising the configuration information and the second trigger pulse.

The above and other aspects will become better understood with regard to the following detailed description of the preferred but non-limiting embodiments. The following description is made with reference to the accompanying drawings.

### BRIEF DESCRIPTION OF THE DRAWINGS

FIG. 1 is a schematic diagram of a timing controller and a driver architecture according to an embodiment

FIG. 2 is a block diagram of a driver according to one embodiment.

FIG. 3 is a waveform diagram of a driver according to one embodiment.

FIG. 4 is a waveform diagram of a driver according to a first embodiment.

FIG. 5 is a waveform diagram of a driver according to a second embodiment.

FIG. 6 is a waveform diagram of a driver according to a third embodiment.

FIG. 7 is a schematic diagram of a conventional source driver.

FIG. 8 is a waveform diagram of a driver according to a first embodiment.

### DETAILED DESCRIPTION OF THE INVENTION

In a driver architecture and driving method thereof of the disclosure, by building a reading circuit and a data input/output start pulse (DIO) generation circuit in a driver, additional data transmission or configuration can be implemented between drivers using DIO wires, so that functions of the drivers can be enhanced without changing an existing architecture.

A driver architecture according to one embodiment includes multiple drivers connected in series. Among the drivers, an (i)^{th} driver includes a reading circuit, a configuration circuit, a clock generator and a DIO generation circuit, where i is a positive integer greater than 1. The reading circuit reads an (i)^{th} DIO outputted from an (i−1)^{th} driver. The (i)^{th} DIO includes an (i−1)^{th} configuration of an (i−1)^{th} driver and an (i)^{th} trigger pulse. The (i)^{th} trigger pulse is for activating the (i)^{th} driver.

The configuration circuit configures an (i)^{th} configuration of the (i)^{th} driver. The clock generator generates an (i+1)^{th} trigger pulse for activating an (i+1)^{th} driver. The DIO generation circuit outputs an (i+1)^{th} DIO to the (i+1)^{th} driver. The (i+1)^{th} DIO includes the (i)^{th} configuration and the (i+1)^{th} trigger pulse. The (i)^{th} configurations are within a configuration period, and the (i+1)^{th} trigger pulses are within a normal operation period.

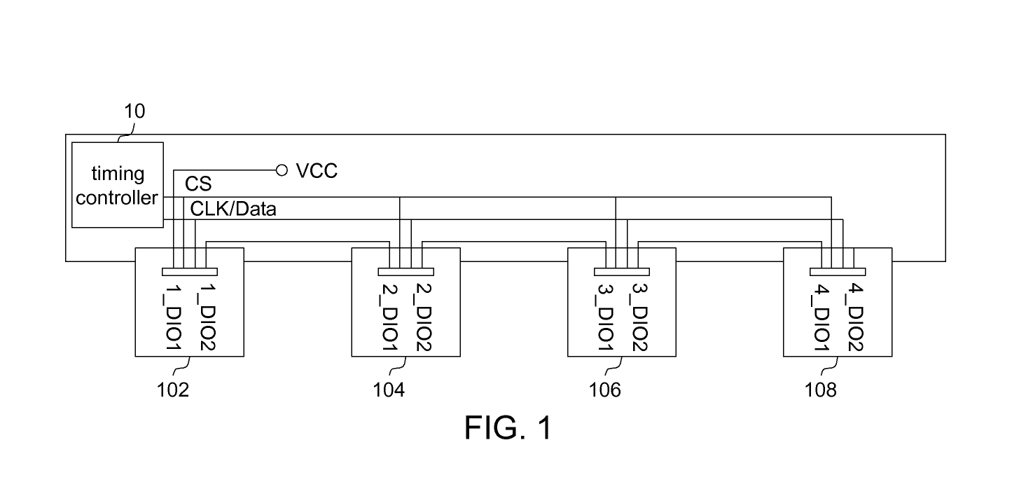

FIG. 1 shows a schematic diagram of a timing controller and a driver driver architecture according to an embodiment based on a mini low-voltage differential signaling (mLVDS) interface. In FIG. 1, four drivers 102 to 108 in a driver architecture are taken as an example for illustration purposes. For example, the drivers 102 to 108 are source drivers or gate drivers. A timing controller 10 outputs a clock signal CLK and a set of data signals to the four drivers 102 and 108, and outputs other control signals to the four drivers 102 to 108. In FIG. 1, Y_DIO1 is a data input start pulse and Y_DIO2 is a data output start pulse, where Y is 1, 2, 3 or 4.

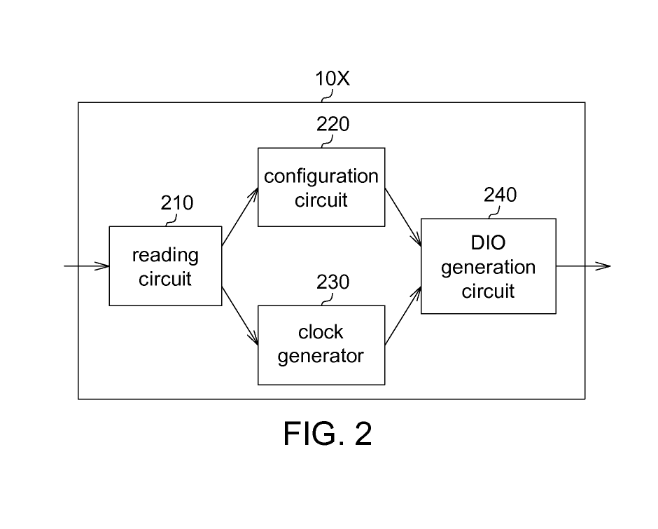

FIG. 2 shows a block diagram of a driver according to one embodiment. A driver 10X includes a reading circuit 210, a configuration circuit 220, a clock generator 230 and a data input/output start pulse (DIO) generation circuit 240, where X is 2, 4, 6 or 8. The reading circuit 210 of the first driver 102 receives an operating voltage VCC to activate the first driver 102; the configuration circuit 220 of the first driver 102 configures a first configuration of the first driver 102; the clock generator 230 of the first driver 102 generates a second trigger pulse for activating the second driver 104; the DIO generation circuit 240 of the first driver 102 outputs a second DIO (1_DIO2) to an input end (2_DIO1) of the second driver 104. The second DIO (1_DIO2) includes the first configuration and the second trigger pulse.

The reading circuit 210 of the second driver 104 reads the second DIO (1_DIO2) outputted from the first driver 102 according to multiple pulses; the configuration circuit 220 of the second driver 104 configures a second configuration of the second driver 104; the clock generator 230 of the second driver 102 generates a third trigger pulse for activating the third driver 106; the DIO generation circuit 240 of the second driver 104 outputs a third DIO (2_DIO2) to an input end 3_DIO1 of the third driver 106. The third DIO (2_DIO2) includes the second configuration and the third trigger pulse. Principles of the third driver 106 and the fourth driver 108 are the same as those of the second driver 104, and shall be omitted herein. The first to fourth configurations are within a configuration period, and the second to fourth trigger pulses are within a normal operation period.

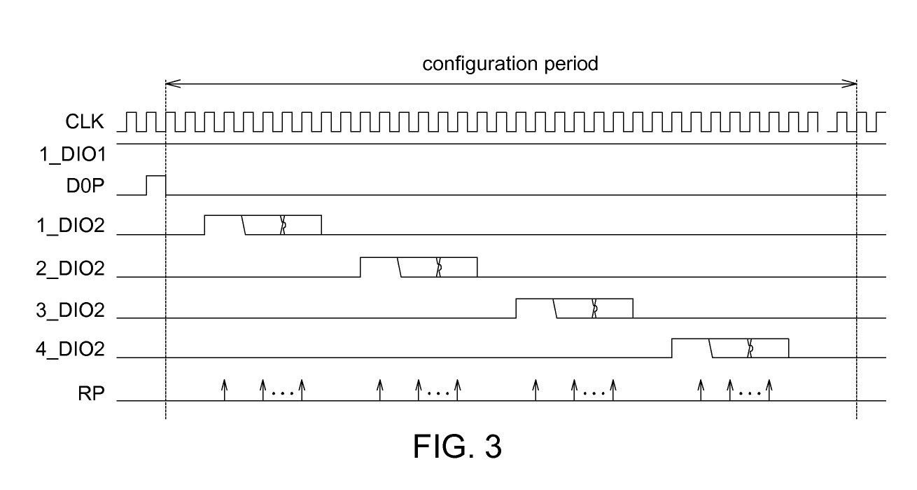

FIG. 3 shows a waveform diagram of a driver according to one embodiment. The reading circuit 210 of the first driver 102 receives the operating voltage VCC via an input pin 1_DIO1, and accordingly determines that it is the first driver and activates; whereas other drivers 104 and 106 determine that they are not the first driver since the operating voltage VCC is not received at the respective input pins 2_IOD1 to 4_DIO1. In FIG. 3, the configuration period is defined as a period from after a reset pulse of a reset signal D0P to an (M)^{th} clock. In the configuration period, for example, the first driver 102 starts to output the second DIO at an (N1)^{th} clock. The second DIO has a starting bit of 1, i.e., a high level.

Based on the second DIO of 1 received, the second driver 104 starts reading configuration information in the received second DIO, and outputs a third DIO after reading (an (N2)^{th} clock). The starting bit of the third DIO is similarly at a high level. Based on the third DIO of 1 received, the third driver 106 starts reading configuration information in the received third third DIO, and outputs a fourth DIO after reading (an (N3)^{th} clock). The starting bit of the fourth DIO is similarly at a high level. Based on the fourth DIO of 1 received, the fourth driver 108 starts reading configuration information in the received fourth DIO, and outputs a fifth DIO after reading (an (N4)^{th} clock). Since the fourth driver 108 is the last driver in this embodiment, the fifth DIO can be omitted and not outputted.

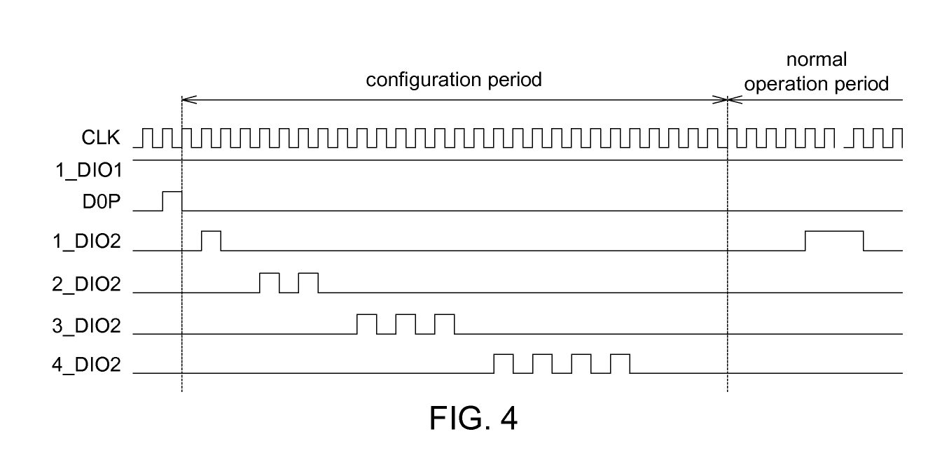

FIG. 4 shows a waveform diagram of a driver according to a first embodiment. The drivers 102 to 108 are taken as an example. The reading circuit 210 of the first driver 102 receives the operating voltage VCC via the input pin 1_DIO1, and accordingly determines that it is the first driver. The first driver 102 outputs one pulse as the first configuration via a DIO output pin 1_DIO2 after an M1 number of clocks subsequent to the reset pulse of the reset signal D0P. The second driver 104 receives the first configuration having one pulse via the DIO input pin 2_DIO1, and accordingly determines that it is the second driver. The second driver 104 outputs two pulses as the second configuration via a DIO output pin 2_DIO2 after an M2 number of clocks.

The third driver 106 receives the second configuration having two pulses via the DIO input in 3_DIO1, and accordingly determines that it is the third driver. The third driver 106 outputs three pulses as the third configuration via a DIO output pin 3_DIO2 after an M3 number of clocks. The fourth driver 108 receives the third configuration having three pulses via the DIO input pin 4_DIO1, and accordingly determines it is the fourth driver. The fourth driver 108 outputs four pulses as the fourth configuration via a DIO output in 4_DIO2 after an M4 number of clocks. In a normal operation period following the configuration period, the drivers 102 to 108 sequentially output the first to fourth trigger pulses, respectively. Thus, the drivers 102 to 108 are allowed to confirm respective sequences, and output correct polarity signals according to respective sequences and channel numbers, for example.

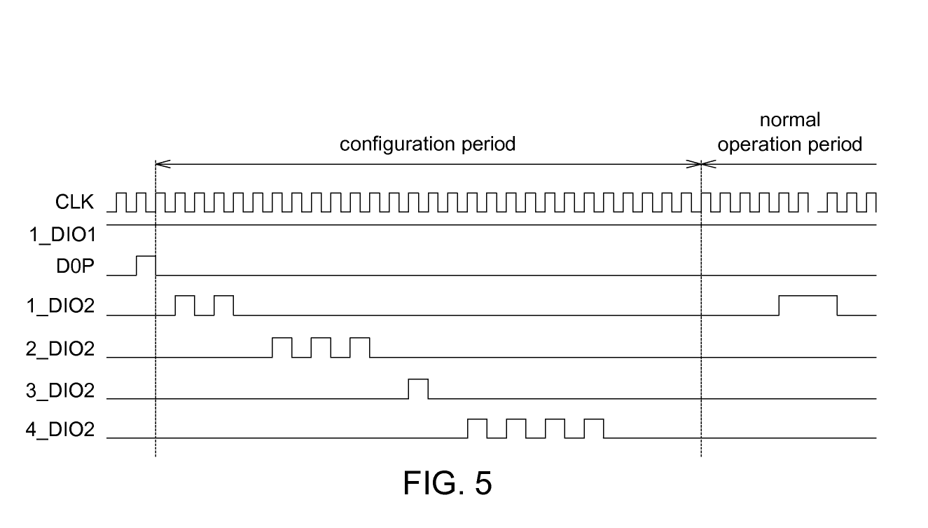

FIG. 5 shows a waveform diagram of a driver according to a second embodiment. The drivers 102 to 108 having different transmission parameters are taken as an example. In FIG. 5, the first driver 102 obtains after operations of the configuration circuit 220 that a parameter to be transmitted is 2, and outputs two pulses as the first configuration via the DIO output pin 1_DIO2 after an M1 number of clocks subsequent to the reset pulse of the reset signal D0P. The second driver 104 receives the first configuration having two pulses via the DIO input pin 2_DIO1, obtains after operations of the configuration circuit 220 of the second driver 104 that the parameter to be transmitted is 3, and outputs three pulses as the second configuration via the DIO output pin 2_DIO2 after an M2 number of clocks.

The third driver 106 receives the second configuration having three pulses via the DIO input pin 3_DIO1, obtains after operations of the configuration circuit 220 of the third driver 106 that the parameter to be transmitted is 1, and outputs one pulse as the third configuration via the DIO output pin 3_DIO2 after an M3 number of clocks. The fourth driver 108 receives the third configuration having one pulse via the DIO input pin 4_DIO1, obtains after operations of the configuration circuit 220 of the fourth driver 108 that the parameter to be transmitted is 4, and outputs four pulses as the fourth configuration via the output pin 4_DIO2 after an M4 number of clocks.

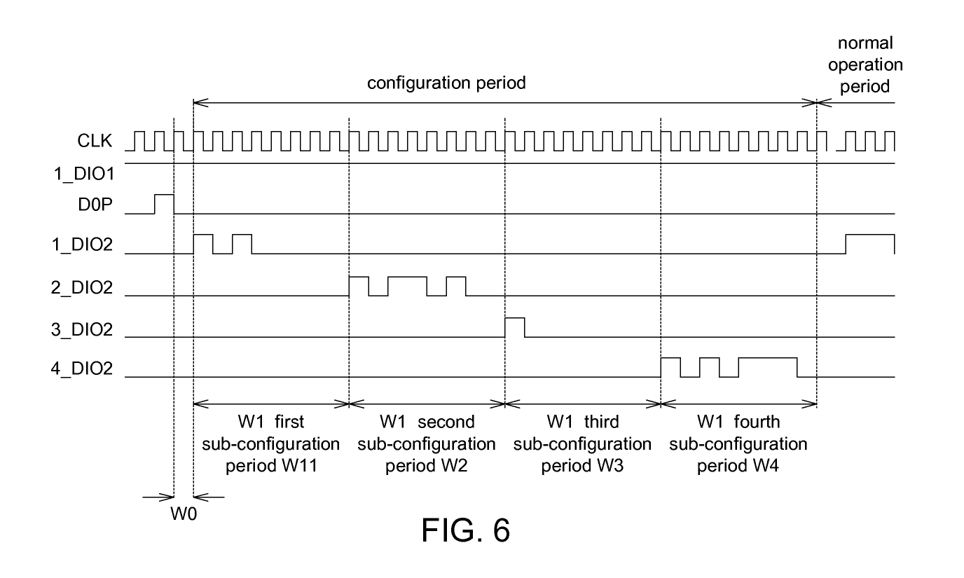

FIG. 6 shows a waveform diagram of a driver according to a third embodiment. The drivers 102 to 108 are taken as an example. The reading circuit 210 of the first driver 210 receives the operating voltage VCC via the input pin 1_DIO1, and accordingly determines it is the first driver. The first driver outputs “10100000” as the first configuration in a first sub-configuration period W1 via the DIO output pin 1_DIO2 after a W0 number of clocks subsequent the reset pulse of the reset signal D0P. The second driver 104 outputs “10110100” as the second configuration in a second sub-configuration period W2 via the DIO output pin 2_DIO2. The third driver 106 outputs “10000000” as the third configuration in a third sub-configuration period W3 via the DIO output pin 3_DIO2. The fourth driver 108 outputs “10101110” as the fourth configuration in a fourth sub-configuration period W4 via the DIO output pin 4_DIO2. Thus, each of the drivers can transmit information using encoded contents in the configurations to the next driver.

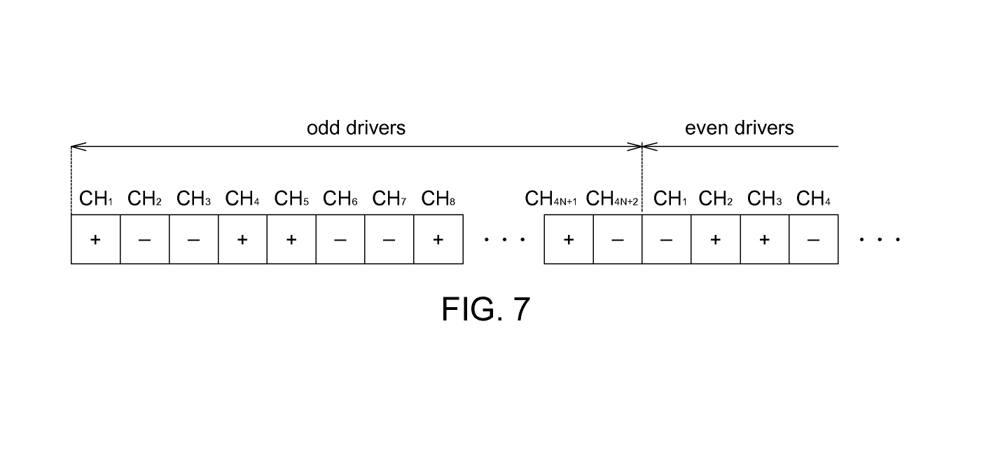

FIG. 7 shows a schematic diagram of a conventional source driver. In FIG. 7, the source driver needs to support an H2dot inversion function, and thus needs to first determine whether it is an odd or even driver. In a conventional approach, an additional configuration pin is utilized for controlling controlling polarity inversion to achieve intersection polarity continuity for the driver.

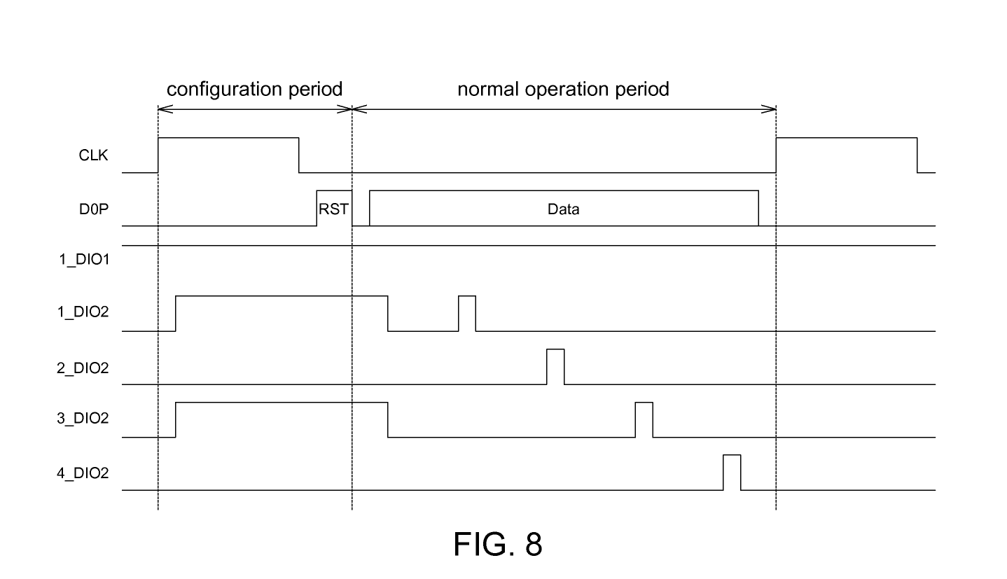

FIG. 8 shows a waveform diagram of a driver according to a fourth embodiment. When an enable signal LD is changed to a high level, the driver first detects the level of the DIO received in order to determine whether it is a lead driver or a cascade driver before entering a configuration period. In the configuration period, the driver may determine a current channel mode and an H2dot configuration to further determine whether a next driver needs to perform polarity inversion.

If the next driver needs to perform polarity inversion, the driver inverts its DIO outputted to inform the next driver. Each driver is then allowed to determine configuration information to be outputted in the configuration period according to the DIO and various configurations of the driver of the previous stage. Further, the driver confirms the status of the driver after the reset pulse of the reset signal D0P to perform associated configurations. After the configuration period, the drivers return to the normal operation mode and access data according to corresponding trigger pulses.

A driving method for a driver architecture is further provided according to an embodiment. The driver architecture includes multiple drivers connected in series. An (i)^{th} driver includes a reading circuit, a configuration circuit, a clock generator and a DIO generation circuit, where i is a positive integer greater than 1. The driving method for the driver architecture includes the following steps. An (i)^{th} DIO outputted from an (i−1)^{th} driver is read by the reading circuit according to multiple reading pulses. The (i)^{th} DIO includes an (i−1)^{th} configuration of the (i−1)^{th} driver and an (i)^{th} trigger pulse. The (i)^{th} trigger pulse is for activating the (i)^{th} driver. An (i)^{th} configuration of the (i)^{th} driver is configured by the configuration circuit. An (i+1)^{th} trigger pulse of an (i+1)^{th} driver is generated by the clock generator. An (i+1)^{th} DIO is outputted to the (i+1)^{th} driver by the DIO generation circuit. The (i+1)^{th} DIO includes the (i)^{th} configuration and the (i+1)^{th} trigger pulse.

Operation principles of the above driving method for a driver architecture are disclosed in descriptions associated FIGS. 1 to 8, and shall be omitted herein.

Therefore, it is demonstrated with the above embodiments that, in a driver architecture and driving method thereof of the disclosure, by building a reading circuit and a DIO generation circuit in a driver, additional data transmission or configuration can be implemented between drivers using DIO wires, so that functions of the drivers can be enhanced without changing an existing architecture.

While the invention has been described by way of example and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A driver architecture, comprising:
a plurality of drivers connected in series, wherein an (i)^{th} driver comprises:
a reading circuit, for reading an (i)^{th} data input/output start pulse (DIO) outputted from an (i−1)^{th} driver according to a plurality of reading pulses; the (i)^{th} DIO comprising configuration information transmitted by the (i−1)^{th} driver and an (i)^{th} trigger pulse, the (i)^{th} trigger pulse being for activating the (i)^{th} driver;
a configuration circuit, for configuring a configuration of the (i)^{th} driver;
a clock generator, for generating an (i+1)^{th} trigger pulse for activating an (i+1)^{th} driver; and
a DIO generation circuit, for outputting an (i+1)^{th} DIO to the (i+1)^{th} driver; the (i+1)^{th} DIO comprising the configuration information and the (i+1)^{th} trigger pulse;
wherein, i is a positive integer greater than 1.

2. The driver architecture according to claim 1, wherein the configurations are within a configuration period, and the (i+1)^{th} trigger pulses are within a normal operation period.

3. The driver architecture according to claim 1, wherein a starting bit of the first configuration is 1.

4. The driver architecture according to claim 1, wherein temporal lengths of the configurations are equal.

5. The driver architecture according to claim 1, wherein each of the configurations comprises an (i)^{th} sequence pulse, such that the (i+1)^{th} driver determines that it is the (i+1)^{th} driver.

6. A driving method for a driver architecture; the driver architecture comprising a plurality of drivers connected in series, the driving method comprising:
reading by an (i)^{th} driver an (i)^{th} data input/output start pulse (DIO) outputted from an (i−1)^{th} driver; the (i)^{th} DIO comprising configuration information and an (i)^{th} trigger pulse, wherein i is a positive integer greater than 1;
activating the (i)^{th} driver by the (i)^{th} trigger pulse;
configuring a configuration of the (i)^{th} driver according to the configuration information;
generating by the (i)^{th} driver an (i+1)^{th} trigger pulse for activating an (i+1)^{th} driver; and
outputting by the (i)^{th} driver an (i+1)^{th} DIO to the (i+1)^{th} driver; the (i+1)^{th} DIO comprising the configuration information and the (i+1)^{th} trigger pulse.

7. The driving method according to claim 6, wherein the configurations are within a configuration period, and the (i+1)^{th} trigger pulses are within a normal operation period.

8. The driving method according to claim 6, wherein a starting bit of the first configuration is 1.

9. The driving method according to claim 6, wherein temporal lengths of the configurations are equal.

10. The driving method according to claim 6, wherein each of the configurations comprises an (i)^{th} sequence pulse, such that the (i+1)^{th} driver determines that it is the (i+1)^{th} driver.

11. A driver architecture, comprising:
a plurality of drivers connected in series, wherein
a first driver of the drivers outputs a data input/output start pulse (DIO) comprising configuration information and a trigger pulse; and
each driver except the first one of the drivers reads a respective first DIO outputted from a precedent driver of the drivers, activated by a respective first trigger pulse in the respective first DIO and configured according to the configuration information in the respective first DIO, and outputs a respective second DIO to a next driver of the drivers, the respective second DIO comprising the configuration information and a respective second trigger pulse.

12. A driver circuit, comprising:
a reading circuit, for reading a data input/output start pulse (DIO), the DIO comprising configuration information for configuring a configuration of the driver circuit and a first trigger pulse for activating the driver circuit;
a configuration circuit, for configuring a configuration of the driver circuit according to the configuration information;
a clock generator, for generating a second trigger pulse for activating another driver; and
a DIO generation circuit, for outputting a DIO signal comprising the configuration information and the second trigger pulse.
